(19) United States
(12) Patent Application Publication
(10) Pub. No.: US 2026/0231362 A1
(43) Pub. Date: Aug. 6, 2026

(54) CONTROLLING FLUID FLOWS USING HYDROPHOBIC SURFACES

(71) Applicant: DELL PRODUCTS L.P., Round Rock, TX (US)

(72) Inventors: Brennan Seal, Austin, TX (US); Trevor Dawson, Austin, TX (US)

(21) Appl. No.: 19/043,951

(22) Filed: Feb. 3, 2025

(51) Int. Cl. H05K 7/20; G06F 1/20; H05K 1/02

(52) U.S. Cl. CPC H05K 7/20272; G06F 1/20; H05K 1/0272; G06F 2200/201; H05K 2203/1173

(57) ABSTRACT

A flow control subsystem for controlling fluid flows affecting an information handling system may include a chassis configured to house components of the liquid-cooled information handling system. The chassis includes at least one hydrophobic region on a surface of the chassis. The surface is a surface that is exposable to a fluid leak. One or more fluid flow channels traverse the hydrophobic region(s). The one or more fluid flow channels are configured to convey fluid away from a predetermined area adjacent to the hydrophobic region.

### FIELD OF THE DISCLOSURE

The present disclosure generally relates to information handling systems, and more particularly relates to liquid cooling of information handling systems.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A flow control subsystem may control fluid flows within a liquid-cooled information handling system. The flow control subsystem may include a chassis configured to house components of the liquid-cooled information handling system. The chassis includes one or more hydrophobic regions on a surface of the chassis that may be exposed to a fluid leak. One or more fluid flow channels traverse the one or more hydrophobic regions. The one or more fluid flow channels may convey fluid away from a predetermined area of the chassis that is adjacent to the hydrophobic region.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a perspective view of an example liquid cooling subsystem for cooling an information handling system;

FIG. 2 is a top view of an exemplary flow control subsystem for an information handling according to an embodiment of the present disclosure;

FIG. 3 is a top view of an exemplary flow control subsystem for an information handling according to another embodiment of the present disclosure;

FIG. 4 is a flow diagram of an example method for controlling fluid flows affecting an information handling system according to an embodiment of the present disclosure; and

FIG. 5 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

For purposes of this disclosure, an information handling system is one that includes a liquid cooling apparatus or sub-system. Such an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, such an information handling system may be a personal computer (such as a desktop or laptop), server (such as a blade server or rack server), a network storage device, or any other suitable device and may vary in size, shape, performance, functionality, and price. The information handling system may include random access memory (RAM), one or more processing resources such as a central processing unit (CPU), graphics processing unit (GPU), hardware and/or software control logic, as well as ROM and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

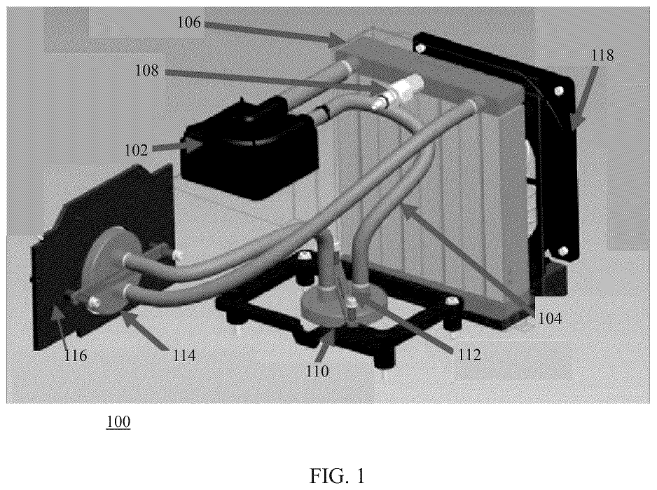

As the processing power of information handling systems continues to increase, the use of liquid cooling is expected to become more common owing to certain advantages that liquid cooling offers over other types of cooling. Referring to FIG. 1, an exemplary liquid cooling system 100 is illustrated. Liquid cooling system 100 illustratively includes pump 102, tubing 104, heat exchanger 106, coolant port 108, CPU cold plate 110, clamp 112, GPU cold plate 114, memory heatsink 116, and fan 118. Pump 102 circulates a coolant such as water or other liquid (e.g., water plus additives) through tubing 104 and heat exchanger 106 to the components of the information handling system, including memory, CPU and/or GPU, as well as other components. The coolant circulates coolant—absorbing heat from the components and cooling the components via the cold plates—in a closed loop within the housing of the information handling system.

Notwithstanding the advantages of liquid cooling, there is the possibility that one or more components of the liquid cooling system may develop leaks over time due to vibration, thermal cycles, aging, misalignment of heat exchangers or cold plates, or the like. Any leak that exposes the components of the information handling system to liquid can cause corrosion or damage to the circuitry within the system's housing. In certain arrangements, a leak occurring in one information handling system also may damage one or more nearby information handling systems if the systems are sufficiently close to one another. For example, a leak may occur in one of multiple servers stacked on a vertical rack (an increasingly common configuration). If the leak is not detected early enough, the coolant may spill out of one server and adversely affect one or more servers below it on the vertical rack.

The risk that a coolant leak in one information handling system may spill over onto another information handling system is especially troublesome given that the number of vertical racks is likely to increase as datacenters expand to deal with high-density data processing tasks such as cloud computing, artificial intelligence, and machine learning. Given the risk, it is important to not only detect coolant leaks rapidly, but also to mitigate a cascade of damage arising from a leak in one information handling system spilling over to one or more systems positioned lower on a vertical rack.

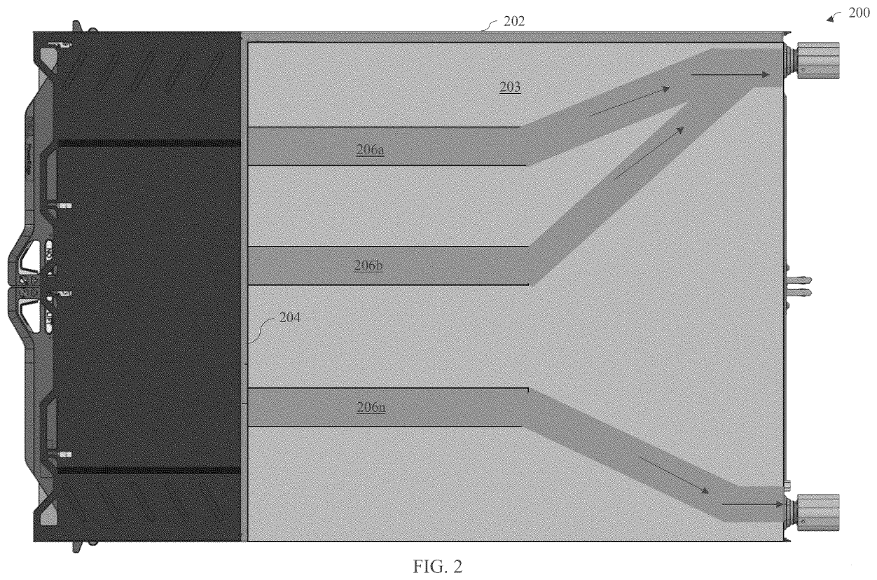

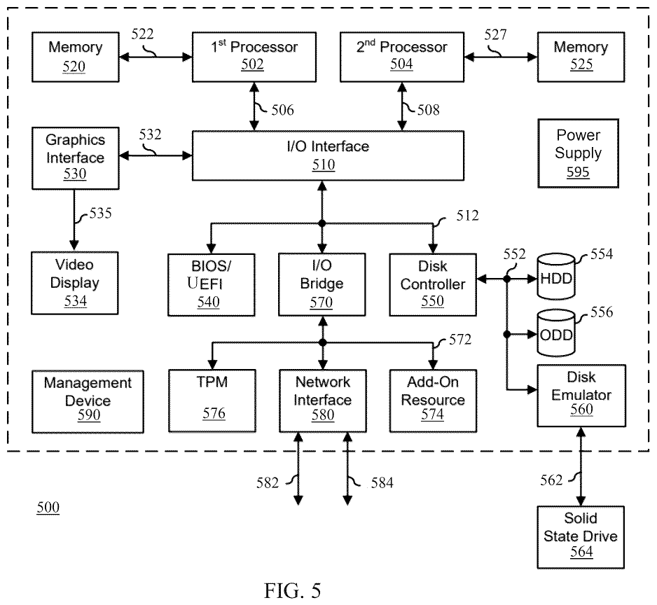

FIG. 2 illustrates a flow control subsystem 200 for controlling liquid flows affecting an information handling system according to at least one embodiment of the present disclosure. Illustratively, flow control subsystem 200 includes chassis 202 configured to house components of the liquid-cooled information handling system. Chassis 202 includes a surface 203, which in turn may include at least one hydrophobic region 204. In an example, surface 203 may be exposed to a fluid leak from a liquid cooling system, such as liquid cooling system 100 of FIG. 1. Flow control subsystem 200 may include one or more fluid flow channels 206a and 206b through 206n, where n is any positive integer, on surface 203. Fluid flow channels 206a-206n illustratively traverse hydrophobic region 204. Fluid flow channels 206a-206n may be configured to convey liquid away from a predetermined area of chassis 202 adjacent to hydrophobic region 204. In an example, the predetermined area adjacent to the hydrophobic region 204 may be a region around one or more components, such as a CPU 502 or 504, GPU 530, or the like of information handling system 500 in FIG. 5.

Hydrophobic region 204, in certain embodiments, may be formed by coating specific surface areas of chassis 202 with a super hydrophobic composite material. The composite material, in some embodiments, may be a fluoropolymer, such as polytetrafluoroethylene (PTFE), which is inherently hydrophobic due to strong carbon-fluorine bonds that are highly resistant to water and other fluids. Various other hydrophobic chemicals can be used to create hydrophobic region(s) 204 in accordance with different embodiments.

Fluid flow channels 206a-206n are formed as a result of different portions of surface 203 not being coated with the hydrophobic coating. Devoid of a hydrophobic coating, fluid flow channels 206a-206n provide a ready avenue for fluid that builds up adjacent to hydrophobic region(s) 204. The accumulation of fluid arising from a coolant leak, for example, can be diverted through fluid flow channels 206a-206n from components or areas encompassed by one or more hydrophobic regions 204. Illustratively, fluid flow channels 206a-206n route the fluid toward the back corners of chassis 202 (in the direction indicated by the arrows), where, at the back corners of the chassis, the fluid may flow off surface 203. Accordingly, hydrophobic region(s) 204 and fluid flow channels 206a-206n can be configured to protect specific components or areas on an internal, or even external, surface 203 of chassis 202.

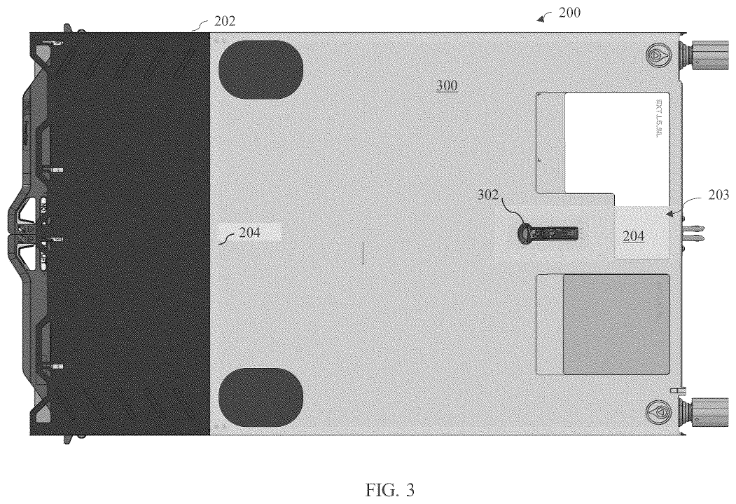

FIG. 3 illustrates an embodiment of flow control subsystem 200 for controlling liquid flows that spill from a higher information handling system on onto chassis 202 of a lower information handling system in a vertical rack according to at least one embodiment of the present disclosure. A particular surface of chassis 202 that may be exposed to the fluid leak from another information handling system higher in the vertical rack is surface 300 of the top cover of the chassis. Illustratively, hydrophobic regions 204 surround top cover latch 302 and extend to the bus bar to prevent leaked fluid from flowing through the latch into the internal region of chassis 202 or flowing off the top cover. Accordingly, flow control subsystem 200 is capable of protecting not only the internal components of the information handling system within chassis 202 but also any other information handling system that may be lower on a vertical rack. Fluid spillovers that build up on top cover surface 300 are repelled from hydrophobic regions 204 so that the fluid accumulates in another area, such as the back end of chassis 202 where it may safely exit the chassis and vertical rack. Depending on the specific configuration, hydrophobic region(s) 204 can repel the fluid so that it exits a certain region. Fluid flow channels 206a-206n may control the fluid flow to certain selected regions intended to mitigate the risk of damage to the components housed by chassis 202 as well as any information handling systems below the chassis. Hydrophobic region(s) 204 are capable of acting as an invisible boundary, such that the hydrophobic regions may prevent fluid from traveling in these regions, but the coating or other material utilized to create these regions may not readily be seen by the human eye.

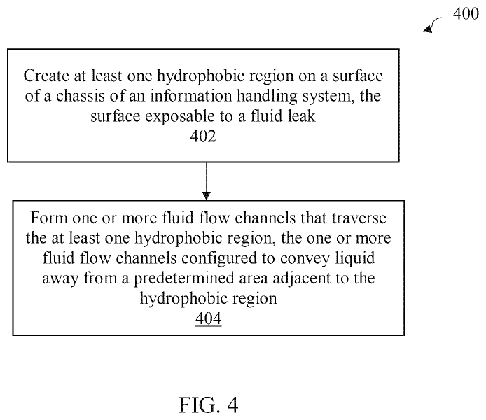

FIG. 4 is a flow diagram of an example method 400 of controlling fluid flows affecting an information handling system according to at least one embodiment of the present disclosure. It will be readily appreciated that not every method step set forth in this flow diagram is always necessary, and that certain steps of the methods may be combined, performed simultaneously, in a different order, or perhaps omitted, without varying from the scope of the disclosure. Method 400 may be performed by a flow control subsystem having certain features of flow control subsystem 200 described with reference to FIGS. 2 and 3.

At block 402, at least one hydrophobic region is created on a surface of a chassis housing components of the information handling system. The hydrophobic region(s) may be coated with a composite material comprising a super hydrophobic coating. The super hydrophobic coating may include a fluoropolymer. The surface of the chassis in which at least one hydrophobic region is created is one that may be exposed to a fluid leak. For example, the chassis may be located within an information handling system positioned on a vertical server rack beneath at least one other information handling system. Hence, the top surface of the chassis may be exposed to a fluid leak that may originate from an information handling system positioned higher in the vertical server rack.

At block 404, one or more fluid flow channels are formed to traverse the at least one hydrophobic surface. The one or more fluid flow channels may be configured to convey fluid away from a predetermined area adjacent to the hydrophobic region. In an example, the at least one hydrophobic region may correspond to an external horizontal surface of a top cover of the chassis. In certain examples, the predetermined area adjacent to the hydrophobic region may be a region around the top cover latch of the top cover of the chassis. The one or more fluid flow channels may be formed to convey fluid away from the top cover latch in response to a buildup of fluid adjacent to the region around the top cover latch.

In other arrangements, the at least one hydrophobic region may correspond to an internal horizontal surface of the chassis. The predetermined area adjacent to the hydrophobic region may be a region around one or more components, such as a CPU, GPU, or the like, of the information handling system. The one or more fluid flow channels may convey fluid away from the one or more processing units in response to a buildup of fluid adjacent to the region around one or more processing units of the information handling system. The fluid buildup may stem from an internal fluid leak from a liquid cooling apparatus or subsystem within the chassis of the information handling system.

FIG. 5 shows a generalized embodiment of an information handling system 500 according to an embodiment of the present disclosure. Information handling system 500 may be substantially like a liquid-cooled information handling system that includes a flow control subsystem such that described with reference to FIGS. 2 and 3. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a computer, a network server, a network storage device, a switch router or other network communication device, or any other suitable device sufficiently sized to include a liquid cooling apparatus or subsystem. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 564, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 564, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532 and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 4394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512 or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500.

Management device 590 can operate off a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

That which is claimed is:

1. A flow control subsystem of an information handling system, the flow control subsystem comprising:
a chassis configured to house components of a liquid-cooled information handling system, wherein the chassis includes at least one hydrophobic region on a surface of the chassis that is exposable to a fluid; and
one or more fluid flow channels traversing the at least one hydrophobic region, wherein the one or more fluid flow channels are configured to convey the fluid away from a predetermined area adjacent to the hydrophobic region.

2. The flow control subsystem of claim 1, wherein the at least one hydrophobic region corresponds to an external horizontal surface of a top cover of the chassis.

3. The flow control subsystem of claim 2, wherein the predetermined area adjacent to the hydrophobic region is a region around a top cover latch of the top cover of the chassis.

4. The flow control subsystem of claim 3, wherein the one or more fluid flow channels convey the fluid away from the top cover latch in response to a buildup of the fluid adjacent to the region around the top cover latch.

5. The flow control subsystem of claim 1, wherein the at least one hydrophobic region corresponds to an internal horizontal surface of the chassis.

6. The flow control subsystem of claim 5, wherein the predetermined area adjacent to the hydrophobic region is a region around one or more processing units of the information handling system.

7. The flow control subsystem of claim 6, wherein the one or more fluid flow channels convey the fluid away from the one or more processing units in response to a buildup of the fluid adjacent to the region around one or more processing units of the information handling system.

8. The flow control subsystem of claim 1, wherein at least one hydrophobic region is coated with a composite material comprising a superhydrophobic coating.

9. The flow control subsystem of claim 8, wherein the superhydrophobic coating comprises a fluoropolymer.

10. A method for controlling fluid flows with an information handling system, the method comprising:
creating at least one hydrophobic region on a surface of a chassis to house components of the information handling system, wherein the surface is exposable to a fluid; and
forming one or more fluid flow channels that traverse the at least one hydrophobic region, wherein the one or more fluid flow channels are configured to convey fluid away from a predetermined area adjacent to the hydrophobic region.

11. The method of claim 10, wherein the at least one hydrophobic region corresponds to an external horizontal surface of a top cover of the chassis.

12. The method of claim 11, wherein the predetermined area adjacent to the hydrophobic region is a region around a top cover latch of the top cover of the chassis.

13. The method of claim 12, wherein the one or more fluid flow channels convey the fluid away from the top cover latch in response to a buildup of the fluid adjacent to the region around the top cover latch.

14. The method of claim 10, wherein the at least one hydrophobic region corresponds to an internal horizontal surface of the chassis.

15. The method of claim 14, wherein the predetermined area adjacent to the hydrophobic region is a region around one or more processing units of the information handling system.

16. The method of claim 15, wherein the one or more fluid flow channels convey the fluid away from the one or more processing units in response to a buildup of the fluid adjacent to the region around one or more processing units of the information handling system.

17. The method of claim 10, wherein at least one hydrophobic region is coated with a composite material comprising a superhydrophobic coating.

18. The method of claim 17, wherein the superhydrophobic coating comprises a fluoropolymer.

19. An information handling system, comprising:
a chassis having a chassis top cover with a top cover latch;
a memory contained within the chassis; and
one or more processing resources contained withing the chassis and operatively coupled with the memory via a bus,
wherein the chassis includes at least one hydrophobic region on a surface of the chassis that is exposable to a fluid, and
wherein one or more fluid flow channels traverse the at least one hydrophobic region and are configured to convey the fluid away from a predetermined area adjacent to the hydrophobic region.

20. The information handling system of claim 19, wherein the at least one hydrophobic region corresponds to an external horizontal surface of the chassis top cover.
